(19) United States
(12) Patent Application Publication
(10) Pub. No.: US 2007/0102785 A1
(43) Pub. Date: May 10, 2007

(54) SEMICONDUCTOR DEVICE WITH FUSE AND METHOD OF FABRICATING THE SAME

(75) Inventor: Ki-Jae HUR, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/557,012

(22) Filed: Nov. 6, 2006

(30) Foreign Application Priority Data
Nov. 9, 2005 (KR) 2005-0107073

(51) Int. Cl. H01L 29/00

(52) U.S. Cl. 257/529

(57) ABSTRACT

A semiconductor device having a fuse and a method of fabricating the same are provided. An embodiment of he semiconductor device includes a fuse pattern having a fuse conductive pattern disposed on a semiconductor substrate and a fuse capping pattern disposed on the fuse conductive pattern. An upper insulating layer is formed to cover the semiconductor substrate having the fuse pattern. A fuse window exposing the fuse pattern through the upper insulating layer is formed. A fuse spacer and a fuse window spacer are disposed on sidewalls of the fuse pattern exposed by the fuse window and sidewalls of the fuse window, respectively.

This application claims the benefit of Korean Patent Application No. 2005-0107073, filed Nov. 09, 2005, the disclosure of which is incorporated by reference.

### BACKGROUND

1. Field of the Invention

The present invention relates to a semiconductor device and a fabrication method thereof and, more particularly, to a semiconductor device with a fuse and a method of fabricating the same.

2. Description of Related Art

Semiconductor memory devices (chips) fabricated on a semiconductor substrate are generally electrically tested before an assembly process. As a result of the testing, the semiconductor memory devices may be classified into bad chips and good chips. If the bad chips malfunction during the testing due to a single failed cell, the failed cell may be replaced by a redundant cell using a repair process. The repair process can include a laser beam irradiation step of blowing predetermined fuses in order for the redundant cell to take on the address of the failed cell for writing and reading modes.

A fuse is generally made of a metal layer, and thus may be protected by an insulating layer before the laser beam irradiation step. A method for protecting the fuse by forming a spacer on sidewalls of the fuse is disclosed in U.S. Pat. No. 6,124,165 (“the '165 patent”). According to the '165 patent, the fuse is simultaneously formed with a bit line, and the top and sidewalls of the fuse are protected by a silicon nitride layer. As a result, the fuse may be protected from damage from outside moisture.

Nevertheless, continuous effort is required to fabricate a semiconductor device with an improved fuse region that can effectively protect the fuse and an inner circuit from outside moisture, while simplifying a process of forming the fuse and a fuse window exposing the fuse.

### SUMMARY

Embodiments of the present invention provide a semiconductor device with a fuse that can simplify a repair process while minimizing failures, and a method of fabricating the same.

In one embodiment, a semiconductor layer with a fuse is provided. The semiconductor device includes a fuse pattern having a fuse conductive pattern disposed on a semiconductor substrate and a fuse capping pattern disposed on the fuse conductive pattern. An upper insulating layer covers the fuse pattern. A fuse window exposing the fuse pattern through the upper insulating layer is formed. A fuse spacer and a fuse window spacer are disposed on sidewalls of the fuse pattern exposed by the fuse window and sidewalls of the fuse window, respectively.

### BRIEF DESCRIPTION OF THE DRAWING

The foregoing and other objects, features and advantages of the invention will be apparent from the detailed description of exemplary embodiments of the invention, as illustrated in the accompanying drawings.

FIG. 1 is a plan view showing part of an array region of a semiconductor device with a fuse according to an exemplary embodiment of the invention.

FIGS. 2 through 10 are cross-sectional views taken along line I-I′ of FIG. 1, which illustrate a fabrication method of a semiconductor device with a fuse.

### DETAILED DESCRIPTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. The drawings may not be to scale, and the thickness of layers and regions may be exaggerated for clarity. Like numbers refer to like elements throughout the specification.

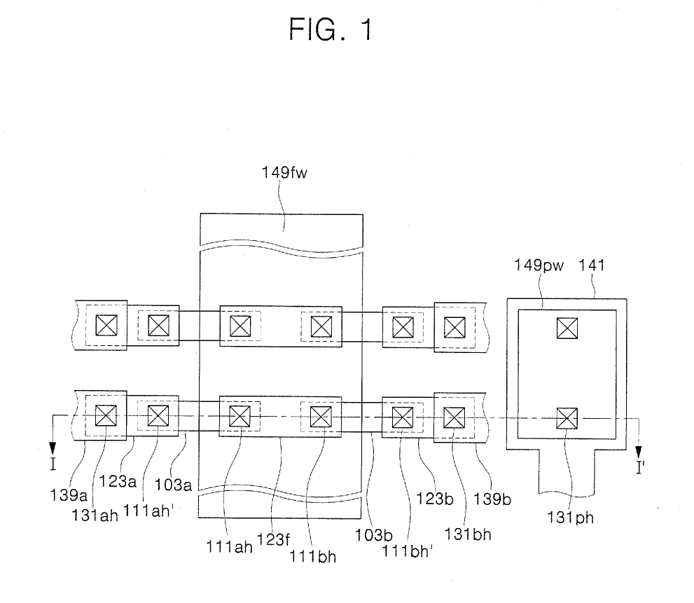

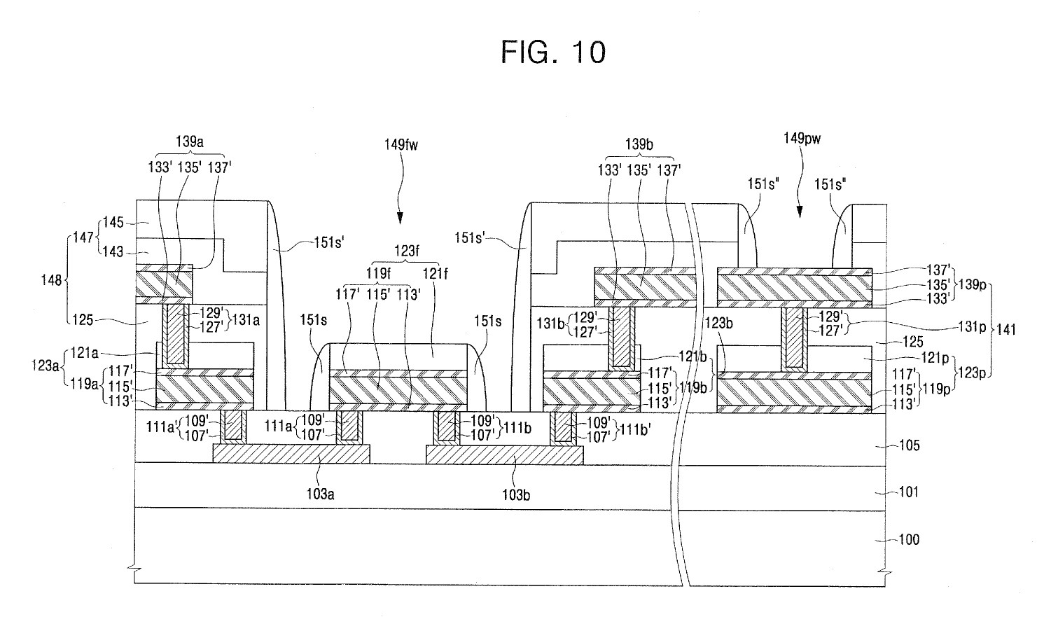

FIG. 1 is a plan view showing part of an array region of a semiconductor device with a fuse according to an exemplary embodiment of the invention. FIG. 10 is a cross-sectional view taken along line I-I′ of FIG. 1.

Referring to FIGS. 1 and 10, an insulating layer 101 is disposed on a surface of a semiconductor substrate 100. First and second lower interconnections 103a and 103b are disposed on the insulating layer 101. The first and second lower interconnections 103a and 103b may be disposed to be at approximately the same height above the insulating layer 101 and may further be spaced apart from each other. As shown in FIG. 1, other lower interconnections may be disposed substantially parallel and adjacent to the first and second lower interconnections 103a and 103b. When the semiconductor device is a semiconductor memory device, the first and second lower interconnections 103a and 103B may be the same conductive layer as a bit line of the semiconductor memory device.

A lower insulating layer 105 is disposed on the surface of the semiconductor substrate having the first and second lower interconnections 103a and 103b. Both ends of the first and second lower interconnections 103a and 103b may be exposed by first and second fuse contact holes (111ah and 111bh of FIG. 1) and first and second lower interconnection contact holes (111ah′ and 111bh′ of FIG. 1) which are disposed through the lower insulating layer 105. The first and second fuse contact holes are respectively filled with first and second fuse contact plugs 111a and 111b, and the first and second lower interconnection contact holes 111ah′ and 111bh′ are respectively filled with first and second lower interconnection contact plugs 111a′ and 111b′. Each contact plug 111a, 111b, 111a′, or 111b′ may include a contact barrier pattern 107′ and a contact pattern 109′ surrounded by the contact barrier pattern 107′. The contact barrier pattern 107′ may be a titanium nitride layer, and the contact pattern 109′ may be a tungsten layer. The contact barrier pattern 107′ may be surrounded by an ohmic layer (not illustrated) such as a titanium layer.

A fuse pattern 123f is disposed to cover the first and second fuse contact plugs 111a and 111b on the lower insulating layer 105. The fuse pattern 123f may include a fuse conductive pattern 119f and a fuse capping pattern 121f, which may be sequentially stacked. The fuse conductive pattern 119f may include a barrier pattern 113′ and a metal pattern 115′ which are stacked. An anti-reflection pattern 117′ may be further provided on the metal pattern 115′. The barrier pattern 113′, the metal pattern 115′, and the anti-reflection pattern 117′ may be formed to respectively include a titanium nitride layer, an aluminum layer, and a titanium nitride layer. The fuse capping pattern 121f may be a silicon nitride layer. First and second intermediate interconnection patterns 123a and 123b are disposed on the lower insulating layer 105 to cover the first and second lower interconnection contact plugs 111a′ and 111b′. The first and second intermediate interconnection patterns 123a and 123b may further be formed to be at approximately the same level as the fuse pattern 123f. The first and second intermediate interconnection patterns 123a and 123b are also disposed at both sides of the fuse pattern 123f. The first and second intermediate interconnection patterns 123a and 123b may be formed of the same or similar material as the fuse pattern 123f. That is, the first intermediate interconnection pattern 123a may include a stacked pattern of a first intermediate interconnection 11 9a and a first interconnection capping pattern 121a disposed the first intermediate interconnection 119a. In the same way, the second intermediate interconnection pattern 123b may include a stacked pattern of a second intermediate interconnection 119b and a second interconnection capping pattern 121b disposed the second intermediate interconnection 119b. The first and second intermediate interconnections 119a and 119b may further be formed of the same or similar material as the fuse conductive pattern 119f, and the first and second interconnection capping patterns 121a and 121b may be formed of a similar material as the fuse capping pattern 121f. That is, the first and second intermediate interconnections 119a and 119b may each include a barrier pattern 113′, a metal pattern 115′, and an anti reflection pattern 117′.

An inter-metal dielectric layer 125 is provided to cover the fuse pattern 123f, the first and second intermediate interconnection patterns 123a and 123b, and the lower insulating layer 105. First and second intermediate interconnection contact holes (131ah and 131bh of FIG. 1) are respectively formed through the inter-metal dielectric layer 125 and the first and second interconnection capping patterns 121a and 121b to respectively expose the first and second intermediate interconnections 119a and 119b. First and second intermediate interconnection contact plugs 131a and 131b are disposed to respectively fill the first and second intermediate interconnection contact holes 131ah and 131bh. Each of the first and second intermediate interconnection contact plugs 131a and 131b may include a contact barrier pattern 127′ and a contact pattern 129′ surrounded by the contact barrier pattern 127′. First and second upper interconnections 139a and 139b are disposed on the inter-metal dielectric layer 125 to cover the first and second intermediate interconnection contact plugs 131a and 131b, respectively. Each of the first and second upper interconnections 139a and 139b may include a stacked pattern of a barrier pattern 133′ and a metal pattern 135′. In addition, each of the first and second upper interconnections 139a and 139b may further include an anti-reflection pattern 137′ disposed on the metal pattern 135′. The barrier pattern 133′, the metal pattern 135′, and the anti-reflection pattern 137′ may respectively include a titanium nitride layer, an aluminum layer, and a titanium nitride layer. A passivation layer 147 is provided to cover the first and second upper interconnections 139a and 139b. The passivation layer 147 may include a stacked layer of an upper passivation layer 145 including a plasma nitride layer and a lower passivation layer 143 including a plasma oxide layer. The passivation layer 147 and the inter-metal dielectric layer 125 may constitute an upper insulating layer 148. A fuse window 149fw is disposed through the upper insulating layer 148, i.e., the passivation layer 147 and the inter-metal dielectric layer 125 to expose the fuse pattern 123f. A fuse spacer 151s may be provided on sidewalls of the fuse pattern 123f exposed by the fuse window 149fw. In addition, a fuse window spacer 151s′ may be provided on sidewalls of the fuse window 149fw. The fuse spacer 151s and the fuse window spacer 151s′ may be formed of a silicon nitride layer.

In one embodiment of the present invention, the fuse conductive pattern 119f is surrounded by the fuse capping pattern 121f and the fuse spacer 151s in order to protect it from damage from outside moisture. Moreover, a fuse window spacer 151s′ is formed on sidewalls of the fuse window 149fw to prevent outside moisture from getting into an inner circuit though the upper insulating layer 148.

A lower bonding pad pattern 123p may be formed to be at approximately the same level as the first and second intermediate interconnection patterns 123a and 123b and the fuse pattern 123f on the lower insulating layer 105. The lower bonding pad pattern 123p may be a stacked pattern of a lower bonding pad pattern 119p and a pad capping pattern 121p disposed thereon. Here, the lower bonding pad 119p and the pad capping pattern 121p may be formed of a similar material as the fuse conductive pattern 119f of the fuse pattern 123f and the fuse capping pattern 121f. A pad contact hole (131ph of FIG. 1) is formed through the inter-metal dielectric layer 125 and the pad capping pattern 121p to expose the lower bonding pad 119p, and a pad contact plug 131p is provided to fill the pad contact hole 131ph. The pad contact plug 131p may be formed of a similar material as the first and second intermediate interconnection contact plugs 131a and 131b. An upper bonding pad 139p is disposed on the inter-metal dielectric layer 125 to cover the pad contact plug 131p. The upper bonding pad 139p may be formed to be at approximately the same level as the first and second upper interconnections 139a and 139b, and formed of a similar material as the first and second upper interconnections 139a and 139b. The upper bonding pad 139p may also be covered with the passivation layer 147 like the first and second upper interconnections 139a and 139b. The lower bonding pad pattern 123p, the pad contact plug 131p, and the upper bonding pad 139p constitute a bonding pad 141.

In another embodiment, the bonding pad 141 may not include the lower bonding pad pattern 123p and the pad contact plug 131p. That is, the bonding pad 141 may be formed of only the upper bonding pad 139p.

A pad window 149pw may be formed through the passivation layer 147 to expose the upper bonding pad 139p. A pad window spacer 151s″ may be provided on sidewalls of the pad window. The pad window spacer 151s″ may be formed of the same or similar material as the fuse spacer 151s. That is, when the fuse spacer 151s is formed of a silicon nitride layer, the pad window spacer 151s″ may also be formed of a silicon nitride layer.

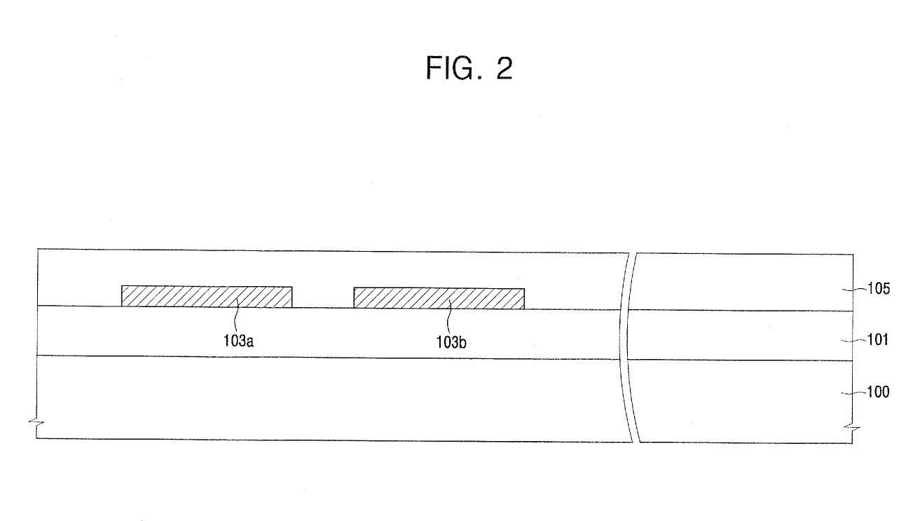

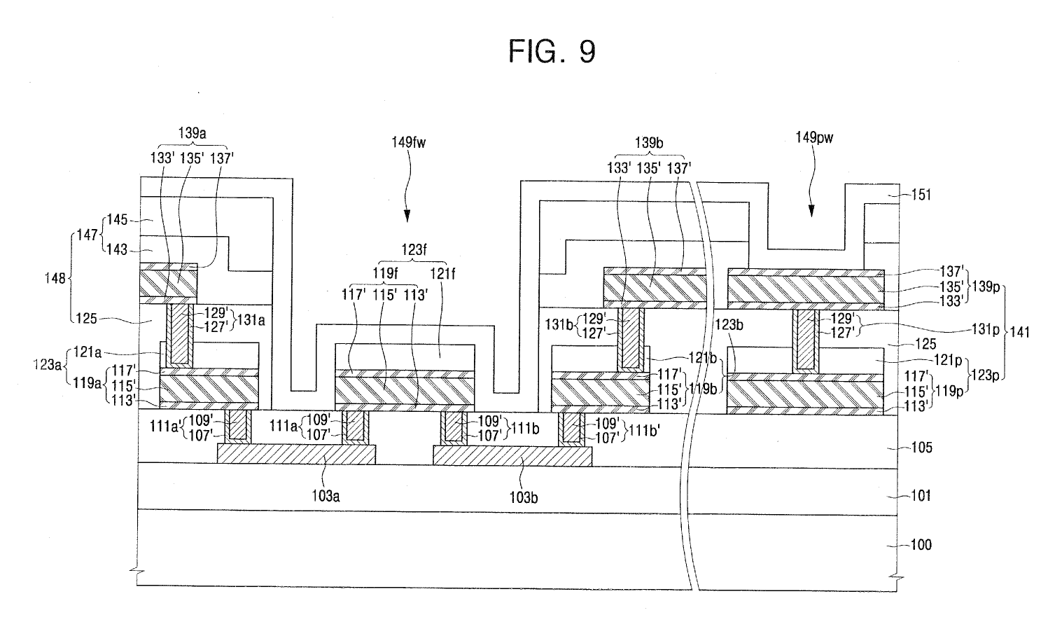

FIGS. 2 through 10 are cross-sectional views taken along line I-I′ of FIG. 1, which illustrate a method of fabricating a semiconductor device according to an exemplary embodiment of the present invention.

Referring to FIGS. 1 and 2, an insulating layer 101 is formed on a surface of a semiconductor substrate 100. When the semiconductor device is a semiconductor memory device, a word line (not illustrated) may be provided under the insulating layer 101. A lower interconnection layer is formed on the insulating layer 101. The lower interconnection layer may be formed of a tungsten layer or a tungsten silicide layer. The lower interconnection layer is patterned to form first and second lower interconnections 103a and 103b which may be spaced apart from each other on the insulating layer 101, The first and second lower interconnections 103a and 103b may be disposed in a substantially straight line. Bit lines (not illustrated) may be simultaneously formed on the insulating layer 101 during the formation of the first and second lower interconnections 103a and 103b. Subsequently, a lower insulating layer 105 is formed on the substrate having the first and second lower interconnections 103a and 103b. The lower insulating layer 105 may be formed of a silicon oxide layer.

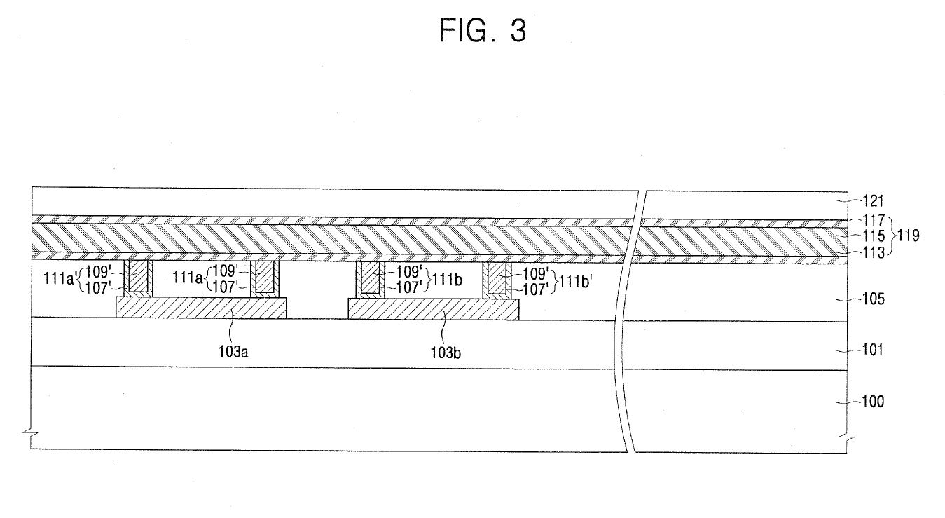

Referring to FIGS. 1 and 3, the lower insulating layer 105 is patterned to form first and second fuse contact holes (111ah and 111bh of FIG. 1) and first and second lower interconnection contact holes (111ah′ and 111bh′ of FIG. 1) exposing both ends of the first and second lower interconnections 103a and 103b. A contact barrier layer and a contact layer may be sequentially formed on the semiconductor substrate having the contact holes 111ah, 111bh, 111ah′, and 111bh′. The contact barrier layer may be formed of a titanium nitride layer, and the contact layer may be formed of a tungsten layer. Before forming the contact barrier layer, an ohmic layer such as a titanium layer may be formed. Further, the lower insulating layer 105 may be exposed by etching back the contact barrier layer and the contact layer. As a result of this etch back, first and second fuse contact plugs 111a and 111b are respectively formed in the first and second fuse contact holes 111ah and 111bh, and first and second lower interconnection contact holes 111a′ and 111b′ are respectively formed in the first and second lower interconnection contact plugs 111ah′ and 111bh′. The first and second fuse contact plugs 111a and 111b and the first and second lower interconnection contact plugs 111a′ 111b′ include a contact barrier pattern 107′ and a contact pattern 109′ surrounded by the contact barrier pattern 107′.

In another embodiment, an etch stop layer (not illustrated) such as a silicon nitride layer may be formed on the lower insulating layer 105 before forming the first and second fuse contact holes 111ah and 111bh and the first and second lower interconnection contact holes 111ah′ and 111bh′. In this case, the contact plugs 111a, 111b, 111a′, and 111b′ are disposed through the etch stop layer as well as through the lower insulating layer 105.

A conductive layer 119 is formed on the lower insulating layer 105 having the contact plugs 111a, 111b, 111a′, and 111b′. The conductive layer 119 may include a barrier layer 113 and a metal layer 115, which are sequentially stacked. The barrier layer 113 and the metal layer 115 may respectively include a titanium nitride layer and an aluminum layer. An anti-reflection layer 117 may be further formed on the metal layer 115. The anti-reflection layer 117 may be a titanium nitride layer. The anti-reflection layer 117 may serve to inhibit corrosion of the metal layer 115 and prevent patterning defects due to diffused reflection in a photolithographic process. A capping layer 121 is formed on the conductive layer 119. The capping layer 121 may be formed of a silicon nitride layer.

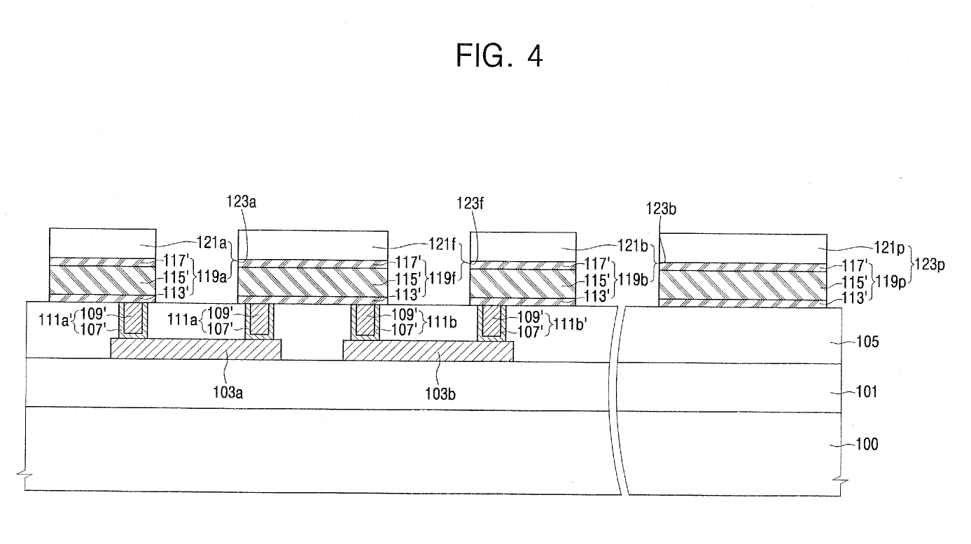

Referring to FIGS. 1 and 4, the capping layer 121 and the conductive layer 119 are patterned to form a fuse pattern 123f, first and second intermediate interconnection patterns 123a and 123b, and a lower bonding pad pattern 123p. The fuse pattern 123p, the first and second intermediate interconnection patterns 123a and 123b, and the lower bonding pad pattern 123p may thus be formed of a stacked pattern of the same material. The fuse pattern 123f includes a fuse conductive pattern 119f and a fuse capping pattern 121f formed on the fuse conductive pattern 119f. The first intermediate interconnection pattern 123a includes a first intermediate interconnection 119a and a first interconnection capping pattern 121a formed on the first intermediate interconnection 119a. Likewise, the second intermediate interconnection pattern 123b includes a second intermediate interconnection 119b and a second interconnection capping pattern 121b formed on the second intermediate interconnection 119b. The lower bonding pad pattern 123p includes a lower bonding pad 119p and a pad capping pattern 121p formed on the lower bonding pad 119p. The fuse conductive pattern 119f may be a stacked pattern of a barrier pattern 113′ and a metal pattern 115′, or a stacked pattern of the barrier pattern 113′, the metal pattern 115′, and an anti-reflection pattern 117′.

The fuse pattern 123f may be formed to cover first and second fuse contact plugs 111a and 111b on a region between the first and second lower interconnections 103a and 103b. The first and second intermediate interconnection patterns 123a and 123b may be formed at both sides of the fuse pattern 123f to cover each of the first and second lower interconnection contact plugs 111a′ and 111b′. The lower bonding pad pattern 123p may be spaced apart from the fuse pattern 123f and the first and second intermediate interconnection patterns 123a and 123b.

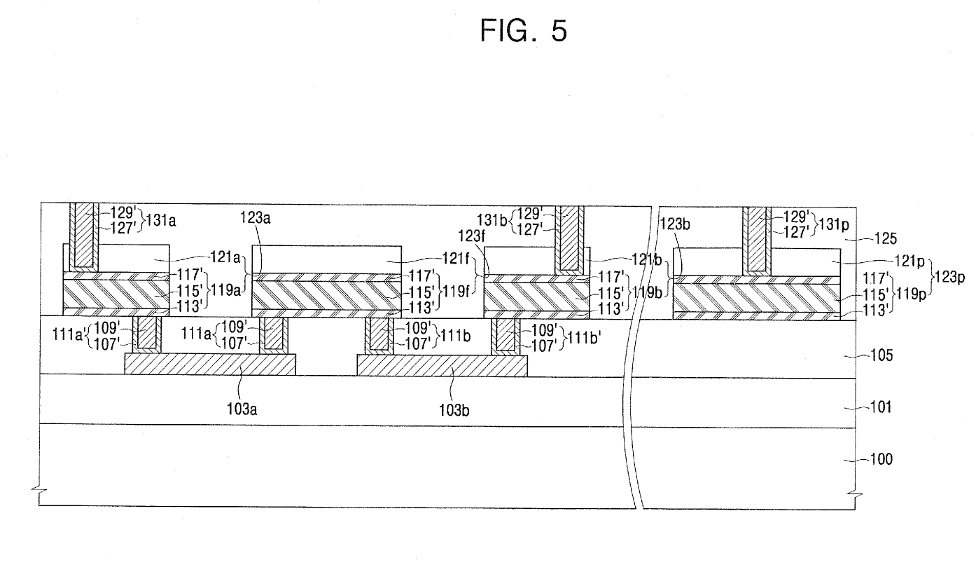

Referring to FIGS. 1 and 5, an inter-metal dielectric layer 125 is formed on the semiconductor substrate 100 having the fuse pattern 123f, the first and second intermediate interconnection patterns 123a and 123b, and the lower bonding pad pattern 123p. The inter-metal dielectric layer 125, the first and second interconnection capping patterns 121a and 121b, and the pad capping pattern 121p may be patterned to respectively form first and second intermediate interconnection contact holes (131ah and 131bh of FIG. 1) and a pad contact hole (131ph of FIG. 1), which respectively expose top surfaces of the first and second intermediate interconnections 119a and 119b and the lower bonding pad 119p. The first and second intermediate interconnection contact holes 131ah and 131bh and the pad contact hole 131ph may be filled with first and second intermediate interconnection contact plugs 131a and 131b and a pad contact plug 131p, respectively. Each of the first and second intermediate interconnection contact plugs 131a and 131b and the pad contact plug 131p may include a contact barrier pattern 127′ and a contact pattern 129′ surrounded by the contact barrier pattern 127′. The contact barrier pattern 127′ and the contact pattern 129′ may be formed of a titanium nitride layer and a tungsten layer, respectively.

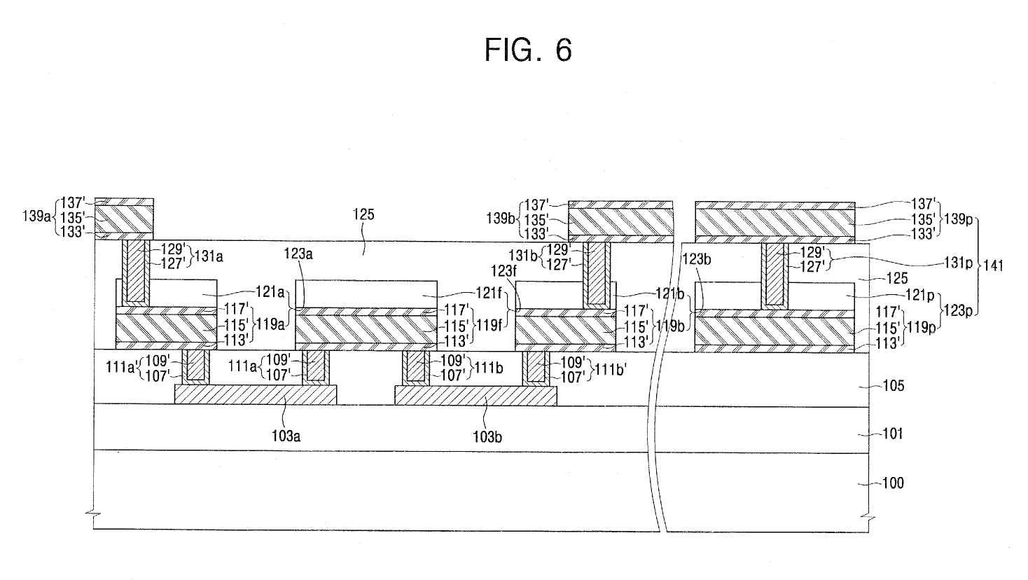

Referring to FIGS. 1 and 6, an upper interconnection layer is formed on the substrate having the contact plugs 131a, 131b, and 131p. The upper interconnection layer may include a barrier layer and a metal layer which are sequentially stacked. In addition, the upper interconnection layer may further include an anti-reflection layer on the metal layer. The barrier layer, the metal layer, and the anti-reflection layer may be formed of a titanium nitride layer, an aluminum layer, and a titanium nitride layer, respectively. The upper interconnection layer may then be patterned to form first and second upper interconnections 139a and 139b and an upper bonding pad 139p. Each of the first and second upper interconnections 139a and 139b and the upper bonding pad 139p may include a barrier pattern 133′, a metal pattern 135′, and an anti-reflection pattern 137′. The first and second upper interconnections 139a and 139b may be formed to cover the first and second intermediate interconnection contact plugs 131a and 131b, respectively. The first upper interconnection 139a may thus be electrically connected to the first intermediate interconnection 119a by the first intermediate interconnection contact plug 131a, and the second upper interconnection 139b may be electrically connected to the second intermediate interconnection 119b by the second intermediate interconnection contact plug 131b. The upper bonding pad 139p may be electrically connected to the lower bonding pad 119p via the pad contact plug 131p. The lower bonding pad pattern 123p, the pad contact plug 131p, and the upper bonding pad 139p constitute a bonding pad 141.

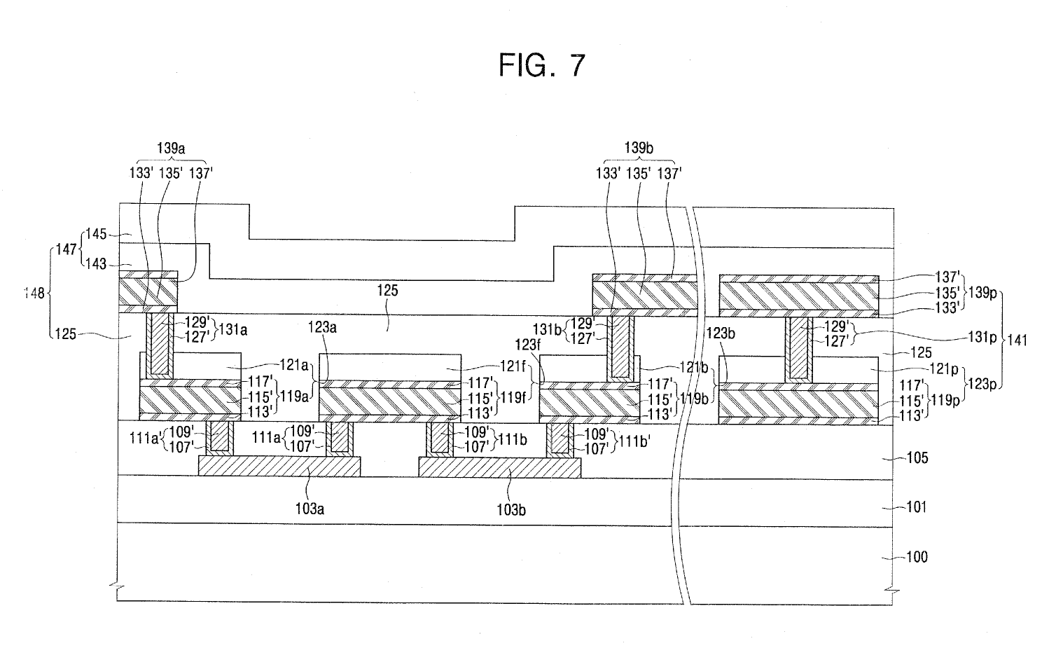

Referring to FIGS. 1 and 7, a lower passivation layer 143 is formed on the surface of the semiconductor substrate 100 having the first and second upper interconnections 139a and 139b, and the upper bonding pad 139p. The lower passivation layer 143 may be formed of a plasma oxide layer. An upper passivation layer 145 is formed on the lower passivation layer 143. The upper passivation layer 145 may be formed of a plasma nitride layer. The upper passivation layer 145 may serve to inhibit outside moisture from penetrating into an integrated circuit formed on the semiconductor substrate 100, and the lower passivation layer 143 may serve as a buffer layer to relieve stress on the upper passivation layer 145. The lower passivation layer 143 and the upper passivation layer 145 constitute a passivation layer 147. The inter-metal dielectric layer 125 and the passivation layer 147 constitute an upper insulating layer 148.

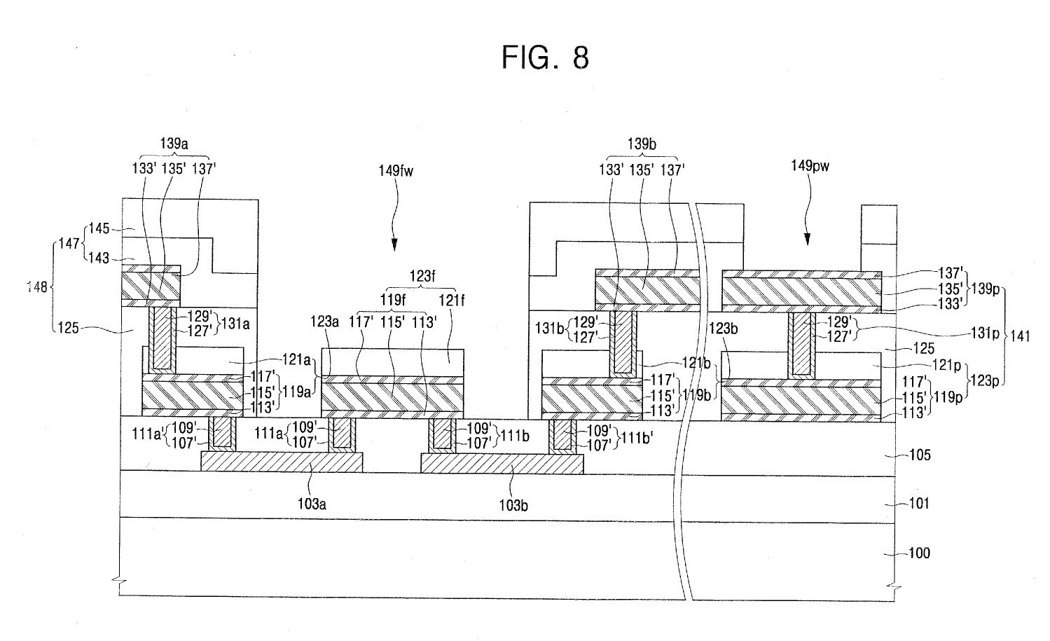

Referring to FIGS. 1 and 8, a pad window 149pw is formed to expose the top surface of the upper bonding pad 139p and a fuse window 149fw is formed to expose the fuse pattern 123f through the upper insulating layer 148. To be specific, openings may be formed at areas where the fuse window 149fw and the pad window 149pw are to be formed by patterning the upper passivation layer 145. The lower passivation layer 143 and the inter-metal dielectric layer 125 may then be etched using the upper passivation layer 145 having the opening as an etching mask. Here, the fuse capping pattern 121f is preferably formed of a material having an etching selectivity with respect to the inter-metal dielectric layer 125 and the lower passivation layer 143. For example, when the lower passivation layer 143 and the inter-metal dielectric layer 125 are formed of an oxide layer, the fuse capping pattern 121f may be formed of a silicon nitride layer. Therefore, the top surface of the fuse conductive pattern 119f is protected by the fuse capping pattern 121f. While forming the fuse window 149fw, the pad window 149pw exposing the top surface of the upper bonding pad 139p may be simultaneously formed. Here, the uppermost layer of the upper bonding pad 139p is formed of the anti-reflection pattern 137′ and may be removed by over-etching.

In the present invention, the fuse window 149fw and the pad window 149pw are formed by performing a patterning process once, thereby simplifying the overall process. Also, a fuse capping pattern 121f is the uppermost layer of the fuse pattern 123f, which may protect the fuse conductive pattern 119f from damage while the fuse window 149fw is formed.

Referring to FIGS. 1, 9, and 10, a fuse spacer layer 151 is formed on the semiconductor substrate 100 having the fuse window 149fw and the pad window 149pw. The fuse spacer layer 151 may be anisotropically etched, thereby forming a fuse spacer layer 151s covering sidewalls of the fuse pattern 123f, a fuse window spacer 151s′ covering sidewalls of the fuse window 149fw and a pad window spacer 151s″ covering sidewalls of the pad window 149pw. The spacers 151s, 151s′, and 151s″ may be formed of a silicon nitride layer. The fuse spacer 151s is formed to cover sidewalls of the fuse pattern 123f exposed by the fuse window 149fw, thereby preventing corrosion of the fuse conductive pattern 123f due to outside moisture. According to the present invention, the fuse window spacer 151s′ and the pad window spacer 151s″ are also formed on sidewalls of the fuse window 149fw and the pad window 149pw, thereby preventing outside moisture from penetrating into an inner circuit.

To protect the semiconductor chip, a polyimide layer (not shown) may be further formed on the substrate having the fuse spacer 151s, the fuse window spacer 151s′ and the pad window spacer 151s″.

According to the present invention as described above, a capping pattern is formed to protect the top surface of the fuse before forming a fuse window, thereby enabling simultaneous formation of a pad window exposing the fuse window and a pad. In addition, spacers are also formed on sidewalls of the fuse window and the pad window, not only on sidewalls of the fuse, thereby protecting an inner circuit from damage due to outside moisture which may permeate through the fuse window and the pad window.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a fuse pattern including a fuse conductive pattern disposed on a semiconductor substrate and a fuse capping pattern disposed on the fuse conductive pattern;
an upper insulating layer covering the semiconductor substrate including the fuse pattern;
a fuse window exposing the fuse pattern through the upper insulating layer; and
a fuse spacer and a fuse window spacer respectively disposed on sidewalls of the fuse pattern exposed by the fuse window and sidewalls of the fuse window.

2. The device according to claim 1, wherein the fuse capping pattern includes a silicon nitride layer.

3. The device according to claim 1, wherein the fuse spacer and the fuse window spacer each include silicon nitride.

4. The device according to claim 1, further comprising:
an intermediate interconnection pattern spaced apart from the fuse pattern on the semiconductor substrate, and including an intermediate interconnection and an interconnection capping pattern disposed on the intermediate interconnection.

5. The device according to claim 4, wherein the intermediate interconnection pattern is formed of the same material as the fuse pattern.

6. The device according to claim 1, wherein the upper insulating layer includes an inter-metal dielectric layer covering the semiconductor substrate including the fuse pattern and a passivation layer disposed on the inter-metal dielectric layer.

7. The device according to claim 6, further comprising:
an upper interconnection disposed on the inter-metal dielectric layer and covered with the passivation layer.

8. The device according to claim 1, further comprising:
a bonding pad disposed on the semiconductor substrate and covered with the upper insulating layer;
a pad window exposing a top surface of the bonding pad through the upper insulating layer; and
a pad window spacer covering sidewalls of the pad window.

9. The device according to claim 8, wherein the bonding pad includes a lower bonding pad pattern disposed at approximately the same level as the fuse pattern, and an upper bonding pad disposed on and electrically connected to the lower bonding pad pattern.

10. The device according to claim 9, wherein the lower bonding pad pattern is formed of the same material as the fuse pattern.

11. A method of fabricating a semiconductor device, comprising:
forming a fuse pattern on a semiconductor substrate, the fuse pattern including a fuse conductive pattern and a fuse capping pattern;
forming an upper insulating layer to cover the semiconductor substrate including the fuse pattern;
forming a fuse window to expose the fuse pattern though the upper insulating layer; and
forming a fuse spacer and a fuse window spacer on sidewalls of the fuse pattern and the fuse window, respectively.

12. The method according to claim 11, wherein the fuse capping pattern includes a silicon nitride layer.

13. The method according to claim 11, wherein the fuse spacer and the fuse window spacer each include a silicon nitride layer.

14. The method according to claim 11, wherein the formation of the fuse spacer and the fuse window spacer includes:
forming a fuse spacer layer on the surface of the semiconductor substrate having the fuse window; and
anisotropically etching the fuse spacer layer.

15. The method according to claim 11, wherein an intermediate interconnection pattern is formed on the semiconductor substrate during the formation of the fuse pattern, the intermediate interconnection pattern being formed at approximately the same level as the fuse pattern and including the same material as the fuse pattern.

16. The method according to claim 11, wherein the formation of the upper insulating layer includes:
forming an inter-metal dielectric layer to cover the semiconductor substrate including the fuse pattern; and
forming a passivation layer on the inter-metal dielectric layer.

17. The method according to claim 16, further comprising forming an upper interconnection on the inter-metal dielectric layer before forming the passivation layer.

18. A method of fabricating a semiconductor device, comprising:
forming a fuse pattern on a semiconductor substrate, the fuse pattern including a fuse conductive pattern and a fuse capping pattern that are sequentially stacked;
forming an inter-metal dielectric layer to cover the semiconductor substrate including the fuse pattern;
forming an upper bonding pad on the inter-metal dielectric layer;
forming a passivation layer to cover the semiconductor substrate including the upper bonding pad;
patterning the inter-metal dielectric layer and the passivation layer to form a pad window exposing the upper bonding pad and a fuse window exposing the fuse pattern; and
forming a fuse spacer, a fuse window spacer, and a pad window spacer on sidewalls of the fuse pattern exposed by the fuse window, the fuse window, and the pad window, respectively.

19. The method according to claim 18, wherein the fuse capping pattern includes a silicon nitride layer.

20. The method according to claim 18, wherein the fuse spacer, the fuse window spacer, and the pad window spacer each include a silicon nitride layer.

21. The method according to claim 18, wherein the formation of the fuse spacer, the fuse window spacer, and the pad window spacer includes:
forming a fuse spacer layer on the semiconductor substrate having the fuse window and the pad window; and
anisotropically etching the fuse spacer layer.

22. The method according to claim 18, wherein an intermediate interconnection pattern is formed on the semiconductor substrate during the formation of the fuse pattern, the intermediate interconnection pattern being formed at approximately the same level as the fuse pattern and including the same material as the fuse pattern.

23. The method according to claim 18, wherein a lower bonding pad pattern is formed during the formation of the fuse pattern, the lower boding pad pattern being formed at approximately the same level as the fuse pattern and including a similar material as the fuse pattern.

24. The method according to claim 18, wherein an upper interconnection is formed on the inter-metal dielectric layer during the formation of the upper bonding pad.
